(19) United States
(12) Patent Application Publication
(10) Pub. No.: US 2026/0190329 A1
(43) Pub. Date: Jul. 2, 2026

(54) MEMORY STRUCTURE AND MANUFACTURING METHOD THEREOF

(71) Applicant: Powerchip Semiconductor Manufacturing Corporation, Hsinchu (TW)

(72) Inventors: Li-Peng Chang, Hsinchu City (TW); San-Jung Chang, Hsinchu City (TW)

(73) Assignee: Powerchip Semiconductor Manufacturing Corporation, Hsinchu (TW)

(21) Appl. No.: 19/035,756

(22) Filed: Jan. 23, 2025

(30) Foreign Application Priority Data
Jan. 2, 2025 (TW) 114100142

(51) Int. Cl. H10B 12/00

(52) U.S. Cl. CPC H10B 12/485; H10B 12/0335

(57) ABSTRACT

A memory structure including a substrate, an isolation structure, a bit line, bit line contacts, and a spacer layer is provided. The isolation structure is located in the substrate. The bit line is located on the substrate and the isolation structure. The bit line contacts are located between the bit line and the substrate. The bit line contacts are separated from each other. The bit line contacts are electrically connected to the bit line. The spacer layer covers the bit line. A portion of the spacer layer is located directly below the bit line.

### CROSS-REFERENCE TO RELATED APPLICATION

This application claims the priority benefit of Taiwan application serial no. 114100142 filed on Jan. 2, 2025. The entirety of the above-mentioned patent application is hereby incorporated by reference herein and made a part of this specification.

### BACKGROUND

### Technical Field

The invention relates to a semiconductor structure and a manufacturing method thereof, and particularly relates to a memory structure and a manufacturing method thereof.

### Description of Related Art

Currently, the parasitic capacitance is easily generated between the bit lines of some memory devices (e.g., dynamic random access memory (DRAM) device), thereby reducing the operating speed of the memory device. Therefore, how to reduce the parasitic capacitance between two adjacent bit lines is the goal of continuous efforts.

### SUMMARY

The invention provides a memory structure and a manufacturing method thereof, which can effectively reduce the parasitic capacitance between two adjacent bit lines, thereby improving the operating speed of the memory structure.

The invention provides a memory structure, which includes a substrate, an isolation structure, a bit line, bit line contacts, and a spacer layer. The isolation structure is located in the substrate. The bit line is located on the substrate and the isolation structure. The bit line contacts are located between the bit line and the substrate. The bit line contacts are separated from each other. The bit line contacts are electrically connected to the bit line. The spacer layer covers the bit line. A portion of the spacer layer is located directly below the bit line.

According to an embodiment of the invention, in the memory structure, the bit line contacts may be connected to the substrate.

According to an embodiment of the invention, in the memory structure, the spacer layer may further cover the sidewalls of the bit line contacts.

According to an embodiment of the invention, in the memory structure, the portion of the spacer layer may be located between the bit line and the isolation structure.

According to an embodiment of the invention, in the memory structure, the portion of the spacer layer may be located between two adjacent bit line contacts. Two adjacent bit line contacts may be separated from each other by the portion of the spacer layer.

According to an embodiment of the invention, in the memory structure, there may be an air gap in the spacer layer. The air gap may be located directly below the bit line.

According to an embodiment of the invention, in the memory structure, the air gap may be located between the bit line and the isolation structure.

According to an embodiment of the invention, in the memory structure, the air gap may be located between two adjacent bit line contacts. Two adjacent bit line contacts may be separated from each other by the air gap.

According to an embodiment of the invention, in the memory structure, there is no air gap in the spacer layer.

According to an embodiment of the invention, in the memory structure, the bit line contacts may be arranged in the extension direction of the bit line.

According to an embodiment of the invention, the memory structure may further include a storage node contact. The storage node contact is located on the substrate aside the bit line.

According to an embodiment of the invention, in the memory structure, the storage node contact may be connected to the substrate.

The invention provides a manufacturing method of a memory structure, which includes the following steps. A substrate is provided. An isolation structure is formed in the substrate. A bit line is formed on the substrate and the isolation structure. Bit line contacts are formed between the bit line and the substrate. The bit line contacts are separated from each other. The bit line contacts are electrically connected to the bit line. A spacer layer covering the bit line is formed. A portion of the spacer layer is located directly below the bit line.

According to an embodiment of the invention, in the manufacturing method of the memory structure, the method of forming the bit line contacts and the bit line may include the following steps. A contact material layer is formed on the substrate. A bit line material layer is formed on the contact material layer. The bit line material layer and the contact material layer are patterned to form the bit line and a patterned contact material layer. A patterned photoresist layer is formed. The patterned photoresist layer exposes a portion of the bit line and a portion of the patterned contact material layer. The portion of the patterned contact material layer is removed by using the patterned photoresist layer as a mask to form the bit line contacts and to form a space directly below the bit line.

According to an embodiment of the invention, in the manufacturing method of the memory structure. the method of removing the portion of the patterned contact material layer is, for example, a wet etching method.

According to an embodiment of the invention, in the manufacturing method of the memory structure, the space may be located between the bit line and the isolation structure.

According to an embodiment of the invention, in the manufacturing method of the memory structure, the space may be located between two adjacent bit line contacts. Two adjacent bit line contacts may be separated from each other by the space.

According to an embodiment of the invention, the manufacturing method of the memory structure may further include the following steps. After forming the bit line contacts, the patterned photoresist layer may be removed.

According to an embodiment of the invention, in the manufacturing method of the memory structure, the method of forming the spacer layer may include the following steps. A spacer material layer is formed on the bit line contacts, the bit line, and the substrate. The spacer material layer fills the space. An etch back process is performed on the spacer material layer to form the spacer layer. The spacer layer fills the space.

According to an embodiment of the invention, the manufacturing method of the memory structure may further include the following steps. A storage node contact is formed on the substrate aside the bit line.

Based on the above description, in the memory structure and the manufacturing method thereof according to the invention, the bit line contacts are separated from each other. The bit line contacts are electrically connected to the bit line. A portion of the spacer layer is located directly below the bit line. Therefore, the parasitic capacitance between two adjacent bit lines can be effectively reduced, thereby improving the operating speed of the memory structure.

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a top view of a memory structure according to some embodiments of the invention.

FIG. 2A to FIG. 2F are cross-sectional views of a manufacturing process of a memory structure taken along section line I-I′ in FIG. 1.

FIG. 2G is a cross-sectional view of a memory structure taken along section line II-II′ in FIG. 1.

FIG. 3A is a cross-sectional view of a memory structure taken along section line I-I′ in FIG. 1 according to other embodiments of the invention.

FIG. 3B is a cross-sectional view of a memory structure taken along section line II-II′ in FIG. 1 according to other embodiments of the invention.

### DESCRIPTION OF THE EMBODIMENTS

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. Furthermore, the features in the top view and the features in the cross-sectional view are not drawn to the same scale. In fact, the dimensions of the various features may be arbitrarily increased or reduced for clarity of discussion.

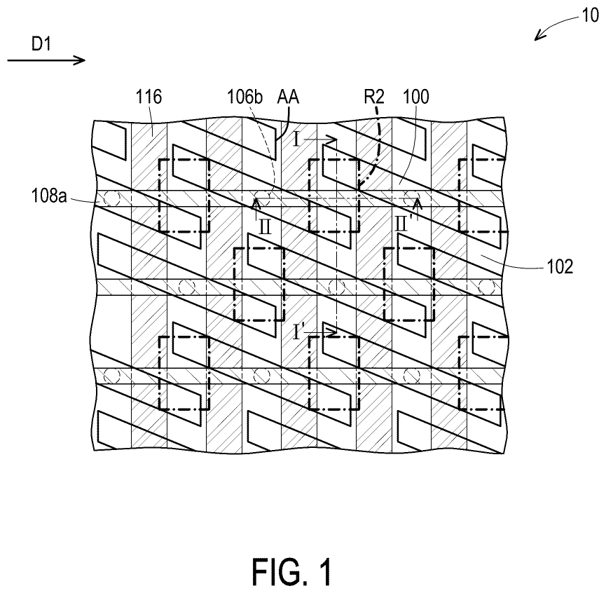

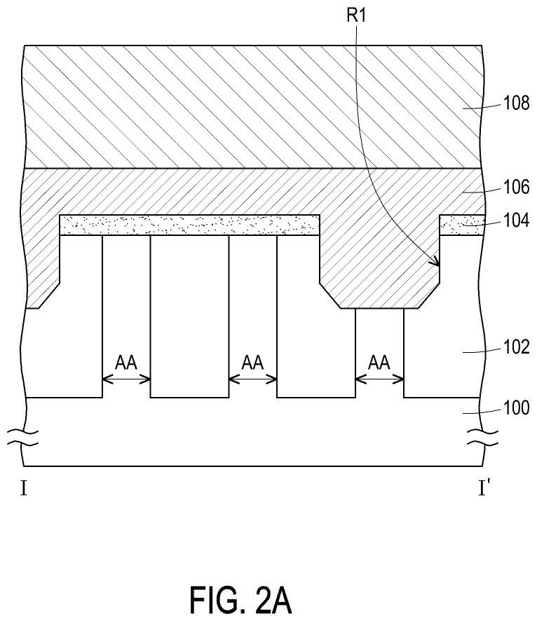

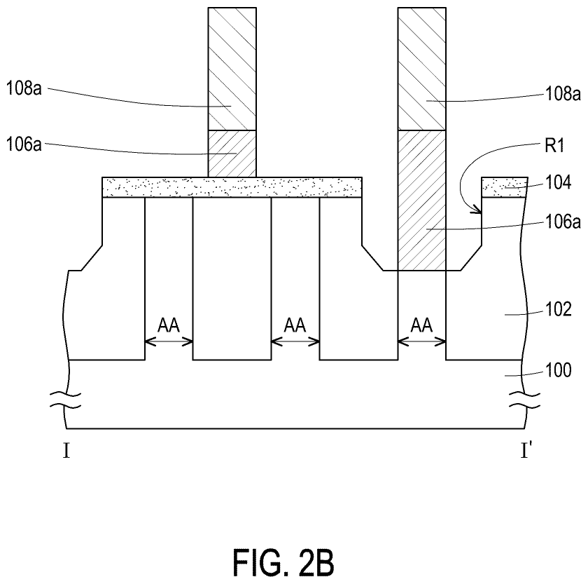

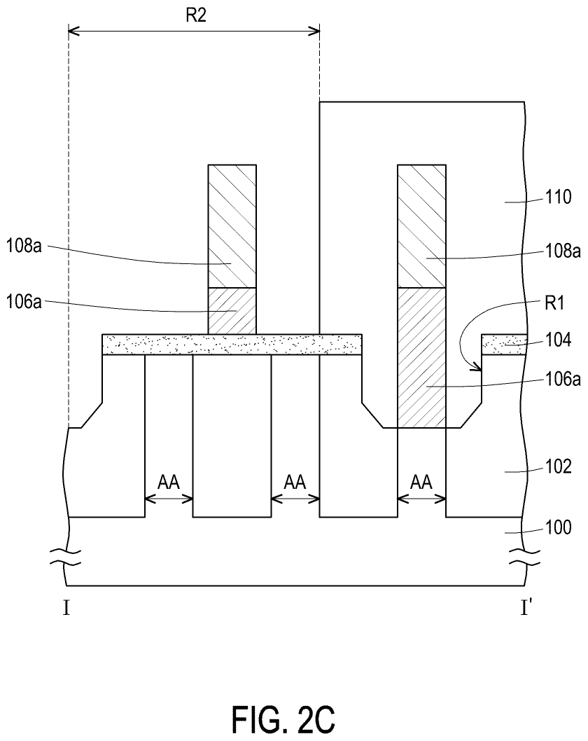

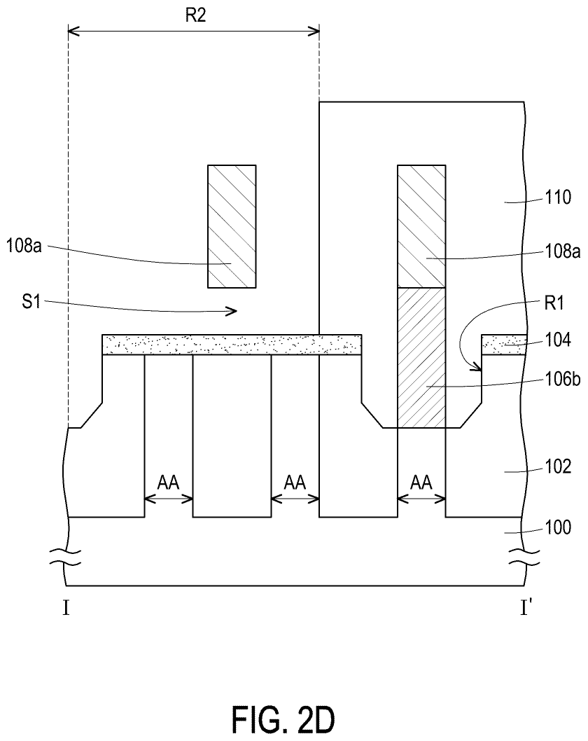

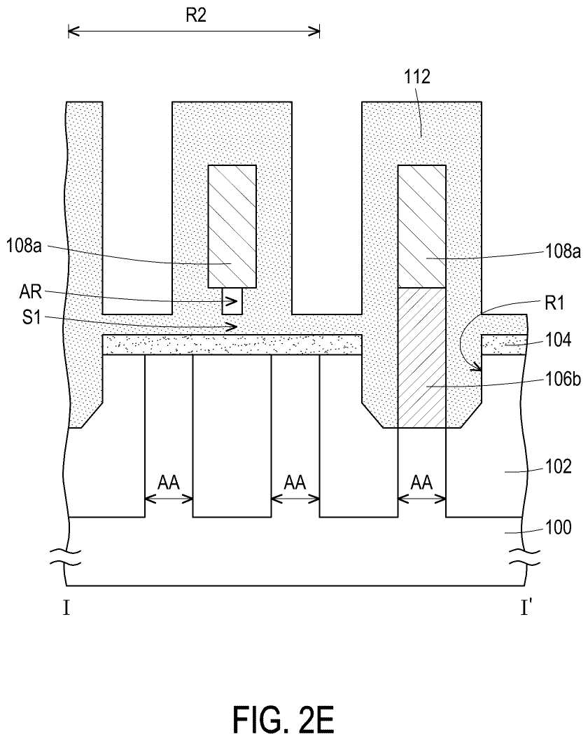

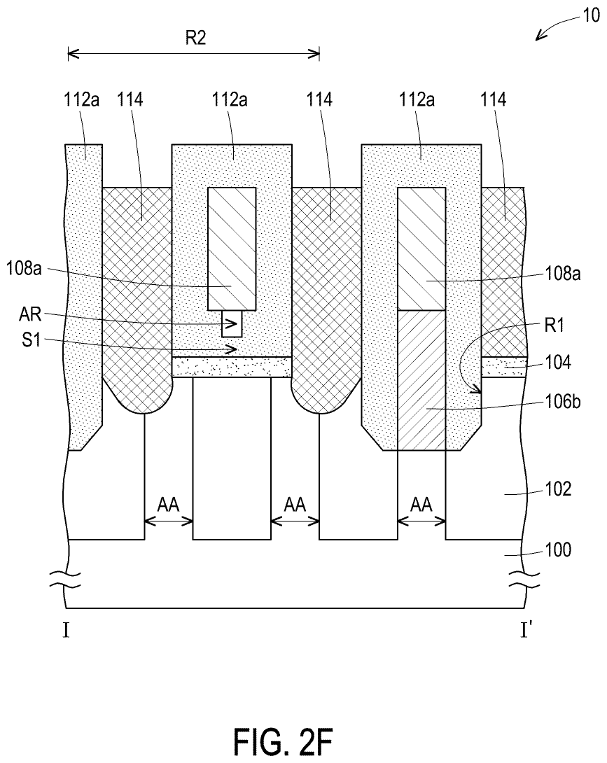

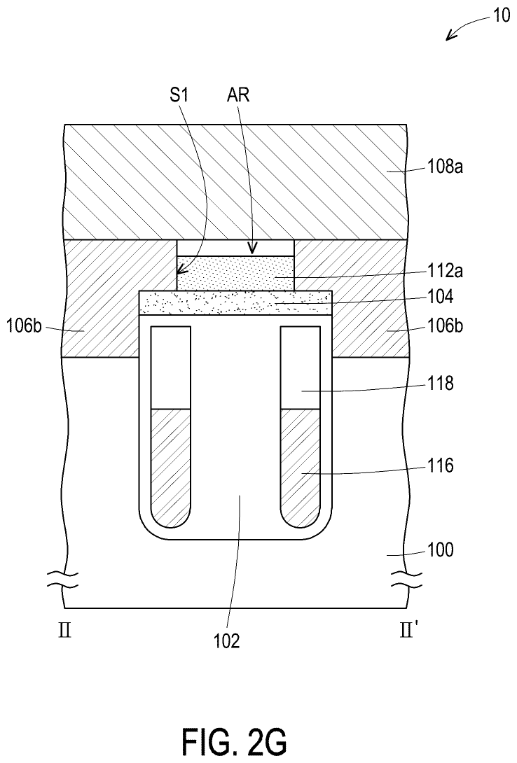

FIG. 1 is a top view of a memory structure according to some embodiments of the invention. FIG. 2A to FIG. 2F are cross-sectional views of a manufacturing process of a memory structure taken along section line I-I′ in FIG. 1. FIG. 2G is a cross-sectional view of a memory structure taken along section line II-II′ in FIG. 1. In FIG. 1, some components in FIG. 2A to FIG. 2G may be omitted to clearly illustrate the configuration relationship between the components in FIG. 1.

Referring to FIG. 1 and FIG. 2A, a substrate 100 is provided. In some embodiments, the substrate 100 may be a semiconductor substrate such as a silicon substrate. An isolation structure 102 is formed in the substrate 100. The isolation structure 102 may define active regions AA in the substrate 100. The isolation structure 102 may be a single-layer structure or a multilayer structure. In some embodiments, the isolation structure 102 may be a shallow trench isolation (STI) structure. In some embodiments, the material of the isolation structure 102 is, for example, silicon oxide. In some embodiments, the isolation structure 102 may be formed by a shallow trench isolation structure process.

A mask layer 104 may be formed on the substrate 100 and the isolation structure 102. In some embodiments, the material of the mask layer 104 is, for example, silicon nitride. In some embodiments, the method of forming the mask layer 104 is, for example, a chemical vapor deposition (CVD) method.

The mask layer 104, the substrate 100, and the isolation structure 102 may be patterned to form a recess R1 in the mask layer 104, the substrate 100, and the isolation structure 102. In some embodiments, the mask layer 104, the substrate 100, and the isolation structure 102 may be patterned by a lithography process and an etching process.

A contact material layer 106 may be formed on the substrate 100. The contact material layer 106 may be further formed on the mask layer 104 and the isolation structure 102 and in the recess R1. In some embodiments, the material of the contact material layer 106 is, for example, doped polysilicon. In some embodiments, the method of forming the contact material layer 106 is, for example, a CVD method.

A bit line material layer 108 may be formed on the contact material layer 106. In some embodiments, the material of the bit line material layer 108 is, for example, tungsten, titanium, titanium nitride, or a combination thereof. In some embodiments, the method of forming the bit line material layer 108 is, for example, a CVD method, a physical vapor deposition (PVD) method, or a combination thereof.

Referring to FIG. 1 and FIG. 2B, the bit line material layer 108 and the contact material layer 106 may be patterned to form a bit line 108a and a patterned contact material layer 106a. Therefore, the bit line 108a may be formed on the substrate 100 and the isolation structure 102. In some embodiments, the bit line material layer 108 and the contact material layer 106 may be patterned by a lithography process and an etching process.

Referring to FIG. 1 and FIG. 2C, a patterned photoresist layer 110 may be formed. The patterned photoresist layer 110 exposes a portion of the bit line 108a and a portion of the patterned contact material layer 106a. For example, the patterned photoresist layer 110 may expose the bit line 108a, the patterned contact material layer 106a, and the mask layer 104 in the region R2. In some embodiments, the patterned photoresist layer 110 may be formed by a lithography process.

Referring to FIG. 1 and FIG. 2D, the portion of the patterned contact material layer 106a may be removed by using the patterned photoresist layer 110 as a mask to form bit line contacts 106b and to form a space S1 directly below the bit line 108a. For example, the patterned contact material layer 106a located in the region R2 may be removed. Therefore, the bit line contacts 106b may be formed between the bit line 108a and the substrate 100. The bit line contacts 106b are separated from each other. The bit line contacts 106b are electrically connected to the bit line 108a. In some embodiments, the space S1 may be located between the bit line 108a and the isolation structure 102. In some embodiments, the space S1 may be located between two adjacent bit line contacts 106b (FIG. 2G). Two adjacent bit line contacts 106b may be separated from each other by the space S1 (FIG. 2G). In some embodiments, a method of removing the portion of the patterned contact material layer 106a is, for example, a wet etching method.

Referring to FIG. 1 and FIG. 2E, after forming the bit line contacts 106b, the patterned photoresist layer 110 may be removed. In some embodiments, the method of removing the patterned photoresist layer 110 is, for example, a dry stripping method or a wet stripping method.

A spacer material layer 112 may be formed on the bit line contacts 106b, the bit line 108a, and the substrate 100. In some embodiments, the spacer material layer 112 may be further formed on the mask layer 104. The spacer material layer 112 fills the space S1. There may be an air gap AR in the spacer material layer 112. The spacer material layer 112 may be a single-layer structure or a multilayer structure. In some embodiments, the material of the spacer material layer 112 is, for example, a low dielectric constant material. In some embodiments, the material of the spacer material layer 112 is, for example, silicon oxycarbide (SiCO). In some embodiments, the method of forming the spacer material layer 112 is, for example, a CVD method.

Referring to FIG. 1 and FIG. 2F, an etch back process may be performed on the spacer material layer 112 to form a spacer layer 112a. The spacer layer 112a fills the space S1. Therefore, the spacer layer 112a covering the bit line 108a may be formed. A portion of the spacer layer 112a is located directly below the bit line 108a. There may be an air gap AR in the spacer layer 112a. In some embodiments, the etch back process is, for example, a dry etching process.

A storage node contact 114 may be formed on the substrate 100 aside the bit line 108a. The storage node contact 114 may pass through the mask layer 104 to connect to the substrate 100. The material of the storage node contact 114 is, for example, doped polysilicon. In some embodiments, the storage node contact 114 may be formed by a combination of a deposition process, a lithography process, and an etching process.

Hereinafter, the memory structure 10 of the above embodiment will be described with reference to FIG. 1, FIG. 2F, and FIG. 2G. In addition, although the method for forming the memory structure 10 is described by taking the above method as an example, the invention is not limited thereto.

Referring to FIG. 1, FIG. 2F, and FIG. 2G, a memory structure 10 includes a substrate 100, an isolation structure 102, a bit line 108a, bit line contacts 106b, and a spacer layer 112a. The isolation structure 102 is located in the substrate 100. The isolation structure 102 may define active regions AA in the substrate 100. The bit line 108a is located on the substrate 100 and the isolation structure 102. The bit line contacts 106b are located between the bit line 108a and the substrate 100. The bit line contacts 106b are separated from each other. The bit line contacts 106b are electrically connected to the bit line 108a. The bit line contacts 106b may be connected to the substrate 100. In some implementations, the bit line contacts 106b may be arranged in the extension direction D1 of the bit line 108a (FIG. 1).

The spacer layer 112a covers the bit line 108a. A portion of the spacer layer 112a is located directly below the bit line 108a. In some embodiments, the spacer layer 112a may further cover the sidewalls of the bit line contacts 106b. In some embodiments, the portion of spacer layer 112a may be located between the bit line 108a and the isolation structure 102. In some embodiments, the portion of the spacer layer 112a may be located between two adjacent bit line contacts 106b (FIG. 2G). Two adjacent bit line contacts 106b may be separated from each other by the portion of the spacer layer 112a (FIG. 2G).

In some embodiments, there may be an air gap AR in the spacer layer 112a. The air gap AR may be located directly below the bit line 108a. In some embodiments, the air gap AR may be located between the bit line 108a and the isolation structure 102. In some embodiments, the air gap AR may be located between two adjacent bit line contacts 106b (FIG. 2G). Two adjacent bit line contacts 106b may be separated from each other by the air gap AR (FIG. 2G).

The memory structure 10 may further include a storage node contact 114. The storage node contact 114 is located on the substrate 100 aside the bit line 108a. The storage node contact 114 may be connected to the substrate 100. The memory structure 10 may further include a mask layer 104. The mask layer 104 is located between the spacer layer 112a and the isolation structure 102.

The memory structure 10 may further include a word line 116. The word line 116 is located in the isolation structure 102. In some embodiments, the word line 116 may be a buried word line. In some embodiments, the material of word line 116 is, for example, tungsten, titanium, titanium nitride, or a combination thereof. The memory structure 10 may further include a mask layer 118. The mask layer 118 is located on the word line 116. In some embodiments, the material of the mask layer 118 is, for example, silicon nitride.

In some embodiments, when the memory structure 10 is a dynamic random access memory (DRAM) structure, the memory structure 10 may further include a capacitor (not shown), and the description thereof is omitted here. In addition, although not shown in the figure, the substrate 100 may have required doped regions, and the description thereof is omitted here.

Based on the above embodiments, in the memory structure 10 and the manufacturing method thereof, the bit line contacts 106b are separated from each other. The bit line contacts 106b are electrically connected to the bit line 108a. A portion of the spacer layer 112a is located directly below the bit line 108a. Therefore, the parasitic capacitance between two adjacent bit lines 108a can be effectively reduced, thereby improving the operating speed of the memory structure 10.

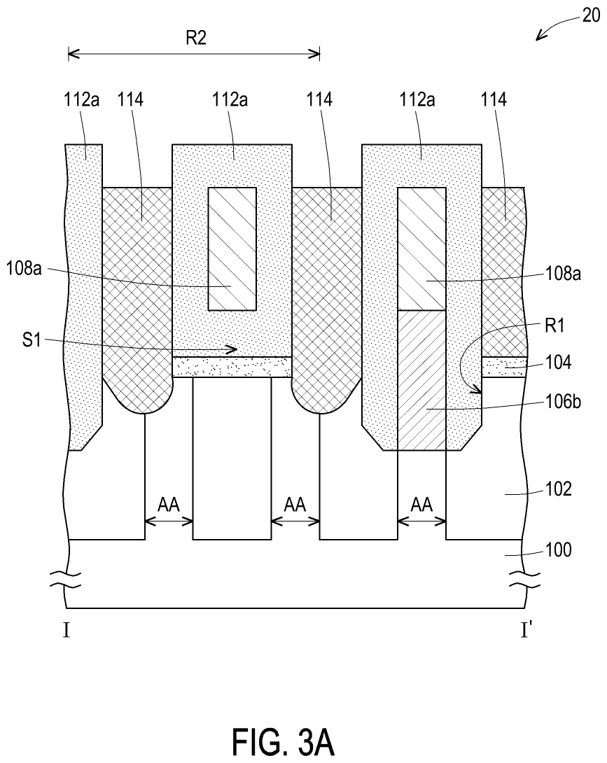

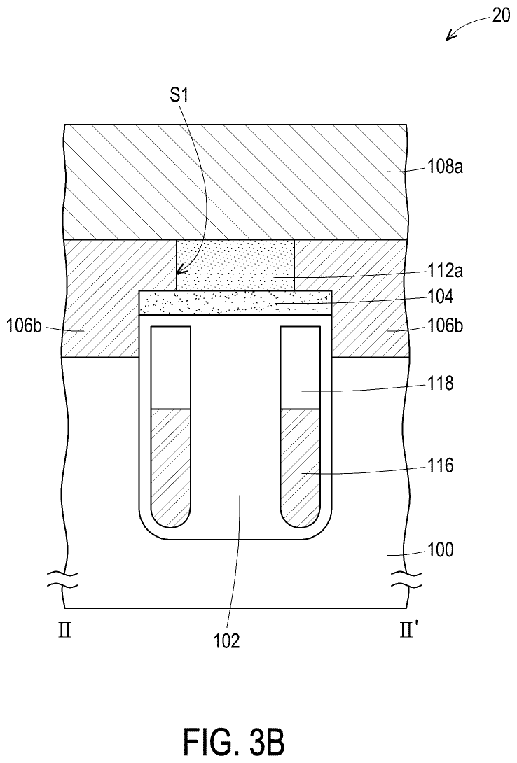

FIG. 3A is a cross-sectional view of a memory structure taken along section line I-I′ in FIG. 1 according to other embodiments of the invention. FIG. 3B is a cross-sectional view of a memory structure taken along section line II-II′ in FIG. 1 according to other embodiments of the invention,

Referring to FIG. 2F, FIG. 2G, FIG. 3A, and FIG. 3B, the difference between the memory structure 20 of FIG. 3A and FIG. 3B and the memory structure 10 of FIG. 2F and FIG. 2G is as follows. In the memory structure 20 of FIG. 3A and FIG. 3B, there is no air gap AR in the spacer layer 112a. In addition, in the memory structure 20 of FIG. 3A and FIG. 3B and the memory structure 10 of FIG. 2F and FIG. 2G, the same or similar components are denoted by the same reference symbols, and the description thereof is omitted.

Based on the above embodiments, in the memory structure 20 and the manufacturing method thereof, the bit line contacts 106b are separated from each other. The bit line contacts 106b are electrically connected to the bit line 108a. A portion of the spacer layer 112a is located directly below the bit line 108a. Therefore, the parasitic capacitance between two adjacent bit lines 108a can be effectively reduced, thereby improving the operating speed of the memory structure 20.

In summary, in the memory structure and the manufacturing method thereof in the aforementioned embodiments, the memory structure includes a substrate, an isolation structure, a bit line, bit line contacts, and a spacer layer. The isolation structure is located in the substrate. The bit line is located on the substrate and the isolation structure. The bit line contacts are located between the bit line and the substrate. The bit line contacts are separated from each other. The bit line contacts are electrically connected to the bit line. The spacer layer covers the bit line. A portion of the spacer layer is located directly below the bit line. Therefore, the parasitic capacitance between two adjacent bit lines can be effectively reduced, thereby improving the operating speed of the memory structure.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A memory structure, comprising:
a substrate;
an isolation structure located in the substrate;
a bit line located on the substrate and the isolation structure;
bit line contacts located between the bit line and the substrate, wherein the bit line contacts are separated from each other and electrically connected to the bit line; and
a spacer layer covers the bit line, wherein a portion of the spacer layer is located directly below the bit line.

2. The memory structure according to claim 1, wherein the bit line contacts are connected to the substrate.

3. The memory structure according to claim 1, wherein the spacer layer further covers sidewalls of the bit line contacts.

4. The memory structure according to claim 1, wherein the portion of the spacer layer is located between the bit line and the isolation structure.

5. The memory structure according to claim 1, wherein the portion of the spacer layer is located between two adjacent bit line contacts, and the two adjacent bit line contacts are separated from each other by the portion of the spacer layer.

6. The memory structure according to claim 1, wherein there is an air gap in the spacer layer, and the air gap is located directly below the bit line.

7. The memory structure according to claim 6, wherein the air gap is located between the bit line and the isolation structure.

8. The memory structure according to claim 6, wherein the air gap is located between two adjacent bit line contacts, and the two adjacent bit line contacts are separated from each other by the air gap.

9. The memory structure according to claim 1, wherein there is no air gap in the spacer layer.

10. The memory structure according to claim 1, wherein the bit line contacts are arranged in the extension direction of the bit line.

11. The memory structure according to claim 1, further comprising:
a storage node contact located on the substrate aside the bit line.

12. The memory structure according to claim 11, wherein the storage node contact is connected to the substrate.

13. A manufacturing method of a memory structure, comprising:
providing a substrate;
forming an isolation structure in the substrate;
forming a bit line on the substrate and the isolation structure;
forming bit line contacts between the bit line and the substrate, wherein the bit line contacts are separated from each other and electrically connected to the bit line; and
forming a spacer layer covering the bit line, wherein a portion of the spacer layer is located directly below the bit line.

14. The manufacturing method of the memory structure according to claim 13, wherein a method of forming the bit line contacts and the bit line comprises:
forming a contact material layer on the substrate;
forming a bit line material layer on the contact material layer;
patterning the bit line material layer and the contact material layer to form the bit line and a patterned contact material layer;
forming a patterned photoresist layer, wherein the patterned photoresist layer exposes a portion of the bit line and a portion of the patterned contact material layer; and
removing the portion of the patterned contact material layer by using the patterned photoresist layer as a mask to form the bit line contacts and to form a space directly below the bit line.

15. The manufacturing method of the memory structure according to claim 14, wherein a method of removing the portion of the patterned contact material layer comprises a wet etching method.

16. The manufacturing method of the memory structure according to claim 14, wherein the space is located between the bit line and the isolation structure.

17. The manufacturing method of the memory structure according to claim 14, wherein the space is located between two adjacent bit line contacts, and the two adjacent bit line contacts are separated from each other by the space.

18. The manufacturing method of the memory structure according to claim 14, further comprising:
removing the patterned photoresist layer after forming the bit line contacts.

19. The manufacturing method of the memory structure according to claim 14, wherein a method of forming the spacer layer comprises:
forming a spacer material layer on the bit line contacts, the bit line, and the substrate, wherein the spacer material layer fills the space; and
performing an etch back process on the spacer material layer to form the spacer layer, wherein the spacer layer fills the space.

20. The manufacturing method of the memory structure according to claim 13, further comprising:
forming a storage node contact on the substrate aside the bit line.
